(19) United States
(12) Patent Application Publication
(10) Pub. No.: US 2014/0174919 A1
(43) Pub. Date: Jun. 26, 2014

(54) ELECTRODE HAVING HEAT SINKS AND COATING DEVICE

(71) Applicant: HON HAI PRECISION INDUSTRY CO., LTD., New Taipei (TW)

(72) Inventor: LI-YING WANG HE, New Taipei (TW)

(73) Assignee: HON HAI PRECISION INDUSTRY CO., LTD., New Taipei (TW)

(21) Appl. No.: 13/864,298

(22) Filed: Apr. 17, 2013

(30) Foreign Application Priority Data
Dec. 24, 2012 (TW) 101149430

(51) Int. Cl. H01J 37/34

(52) U.S. Cl. CPC H01J 37/3438
USPC 204/298.09

(57) ABSTRACT

An electrode is made of conductive material, and includes a first surface, a second surface, and two opposite side surfaces. The second surface is opposite to the first surface. The two side surfaces are connected to the first surface and the second surface. A number of heat sinks are positioned on the second surface and the two first side surfaces, and are configured for exhausting heat generated by the electrode.

### BACKGROUND

1. Technical Field

The present disclosure relates to an electrode having a heat sink and a coating device including the electrode.

2. Description of Related Art

Currently, plastic workpieces are coated using a vacuum sputtering method, but the plastic workpiece need to contact with an electrode. When the electrode is in use for a time period, a great amount of heat is generated to make the temperature of the electrode increase. The heat is transmitted to the plastic workpiece, and the plastic workpiece may be damaged to influence the quality of the plastic workpieces.

Therefore, it is desirable to provide an electrode and a coating device that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a coating device, according to an exemplary embodiment.

FIG. 2 is a schematic, exploded view of the coating device of FIG. 1.

FIG. 3 is a schematic, cross-sectional view of the coating device taken along a line III-III of FIG. 1.

### DETAILED DESCRIPTION

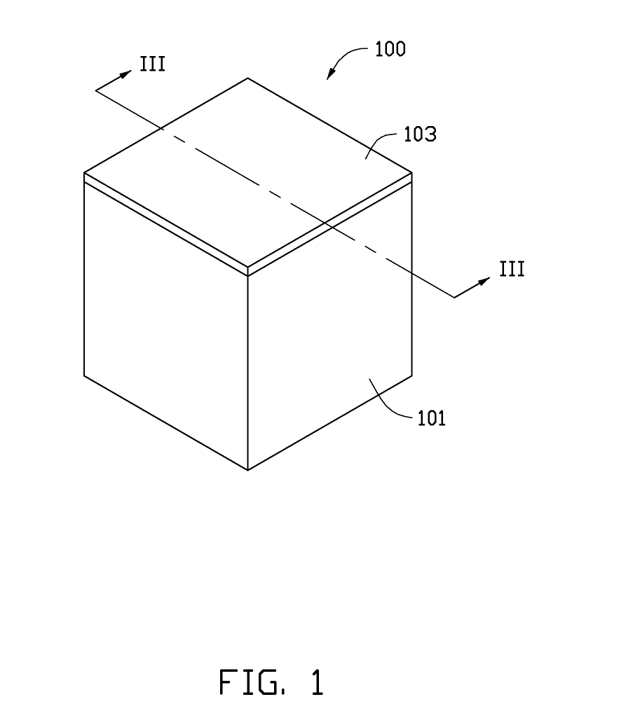

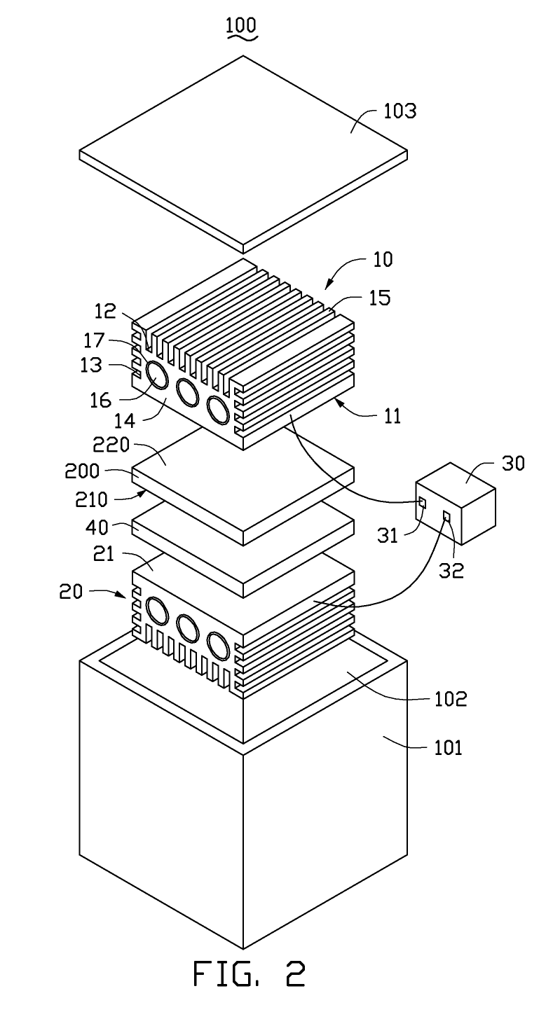

FIG. 1 and FIG. 2 illustrate a coating device 100 in accordance with an embodiment. The coating device 100 is used for coating a plastic workpiece 200. The plastic workpiece 200 includes a pre-coated surface 210 and a fixing surface 220 opposite to the pre-coated surface 210. In the embodiment, the plastic workpiece 200 is a light guide plate.

The coating device 100 has a hermetical hollow working container 101, a first electrode 10, a second electrode 20, and a power source 30. The first electrode 10, the second electrode 20, and the power source 30 are received in the working container 101.

The working container 101 has an opening 102 sealed by a cover 103.

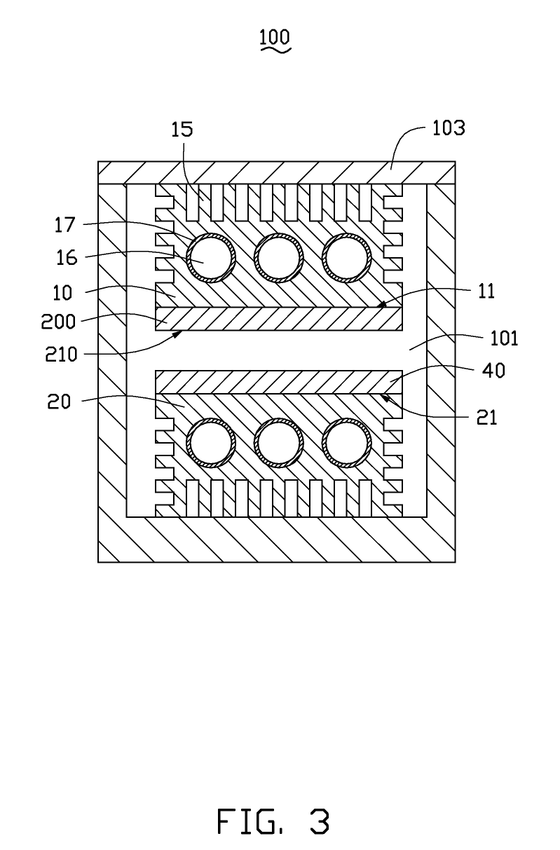

Also referring to FIG. 3, the first electrode 10 is made of conductive material (such as metal). The first electrode 10 is substantially cubic, and includes a first surface 11, a second surface 12, two opposite first side surfaces 13, and two opposite second side surfaces 14. The second surface 12 is opposite to the first surface 11. All of the two first side surfaces 13 and the two second surfaces 14 are connected to the first surface 11 and the second surface 12. The two second side surfaces 14 are connected to the two first side surfaces 13. The first surface 11 is a flat surface, and the second surface 12 and the two first side surfaces 13 are positioned a number of heat sinks 15 evenly spaced from each other.

The heat sinks 15 are used for exhausting the heat generated by the first electrode 10 during working process. The first electrode 10 defines a number of cooling slots 16 passing through the two second side surfaces 14. A pipe 17 is received in each of the cooling slots 16, and is attached to an inner sidewall of the corresponding slot 16. The pipes 17 are made of heat conductive and dielectric material (such as silicon dioxide, or graphite). The pipe 17 communicates with a cooling liquid source (not shown), and thus the cooling liquid can flow into the pipe 17 to cool the heat of the first electrode 10 during working process.

The structure of the second electrode 20 is substantially the same as the structure of the first electrode 10, and is made of conductive material (such as metal). The second electrode 20 has a third surface 21. The third surface 21 is a flat surface.

The first surface 11 is opposite to the third surface 21, and is parallel to the third surface 21.

The power source 30 has an anode 31 electrically connected to the first electrode 10, and a cathode 32 electrically connected to the second electrode 20, and thus an electrical filed is formed between the first electrode 10 and the second electrode 20.

The fixing surface 220 of the plastic workpiece 200 is fixed to the first surface 11. A target 40 is fixed to the third surface 21, and thus the target 40 faces the pre-coated surface 210.

In use, the working container 101 is vacuumed, and then is filled with a working gas (such as argon gas), the power source 30 is turned on to form the electrical field between the first electrode 10 and the second electrode 20, and the argon gas is ionized to form argon ions and free electrons, and the argon ions accelerate towards the target 40, and thus a number of target atoms are separated from the target 40 to move in the working container 101 until arriving at the pre-coated surface 210. The heat sinks 15 exhaust the heat generated by the first electrode 10 and the heat generated by the second electrode 20 during working process, the cooling liquid flows into the pipes 17 to cool the first electrode 10 and the second electrode 20, and thus the temperature of the first electrode 10 and the second electrode 20 would not be increased.

By employing the coating device 100, the first electrode 10 and the second electrode 20 can be effectively cooled, and thus the temperature of the first electrode 10 and the second electrode 20 would not be increased, and thus the plastic workpiece 200 would not be damaged, and the quality of the plastic workpiece 200 can be improved.

In other embodiments, the two second side surfaces 14 also can position the heat sinks 15.

In other embodiments, the pipe 17 can be omitted, and the cooling liquid must be non-electrical conductive liquid, such as distilled water or pure organic solvent (such as ethylene glycol).

In other embodiments, because the second electrode 20 does not contact with the plastic substrate 200, and thus the second electrode 20 does not need to position the heat sinks 15 and the cooling slot 16.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. An electrode made of conductive material, and comprising:
a first surface;
a second surface opposite to the first surface;
two first side surfaces opposite to each other and connected to the first surface and the second surface; and
a plurality of heat sinks positioned on the second surface and the two first side surfaces and configured for exhausting heat generated by the electrode.

2. The electrode of claim 1, comprising two second side surfaces opposite to each other and connected to the first surface, the second surface, and the two first side surfaces, wherein the electrode further defines a plurality of cooling slots passing through the two second side surfaces, and the cooling slots are configured to be filled with cooling liquid to cool the electrode.

3. The electrode of claim 2, comprising a plurality of pipes, wherein each of the pipes is made of heat conductive and dielectric material, is received in a respective one of the cooling slots and is attached to an inner sidewall of the respective cooling slot, and the pipes are configured to be filled with the cooling liquid.

4. The electrode of claim 1, wherein the heat sinks are evenly spaced with each other.

5. The electrode of claim 1, wherein the first surface is a flat surface.

6. A coating device for coating a plastic workpiece having a pre-coated surface, the coating device comprising:
a hermetic working container;
a first electrode made of conductive material, and comprising:
a first surface;
a second surface opposite to the first surface; and
two opposite first side surfaces connected to the first surface and the second surface; and
a plurality of heat sinks positioned on the second surface and the two first side surfaces and configured for exhausting heat generated by the first electrode;
a second electrode aligned with the first electrode; and
a power source comprising:
an anode electrically connected to the first electrode; and
a cathode electrically connected to the second electrode;
wherein the plastic workpiece and a target are positioned between the first electrode and the second electrode, the plastic workpiece is fixed on the first surface, the pre-coated surface faces the second electrode and is separated from the second electrode by the target, and the target is fixed on the second electrode.

7. The coating device of claim 6, wherein the plastic workpiece has a fixing surface opposite to the pre-coated surface, and the fixing surface is fixed on the first surface.

8. The coating device of claim 6, wherein the first electrode comprises two opposite second side surfaces connected to the first surface, the second surface, and the two first side surfaces, wherein the electrode defines a plurality of cooling slots passing through the two second side surfaces, and the cooling slots are filled with cooling liquid to cool the electrode.

9. The coating device of claim 8, wherein the first electrode comprises a plurality of pipes, each of the pipes is made of heat conductive and dielectric material, is received in a respective one of the cooling slots and is attached to an inner sidewall of the respective cooling slot, and the cooling liquid is filled with in the pipes.

10. The coating device of claim 6, wherein the heat sinks are evenly spaced with each other.

11. The coating device of claim 6, wherein the first surface is a flat surface.

12. The coating device of claim 6, wherein the structure of the second electrode is the same as the structure of the first electrode.
